(19) United States
(12) Patent Application Publication
(10) Pub. No.: US 2026/0328305 A1
(43) Pub. Date: Oct. 22, 2026

(54) DUAL-CHANNEL MONOBLOCK GAS MANIFOLD

(71) Applicant: Lam Research Corporation, Fremont, CA (US)

(72) Inventor: Prahalad Narasinghdas Agarwal, Bangalore (IN)

(21) Appl. No.: 19/104,667

(22) PCT Filed: Aug. 18, 2023
(86) PCT No.: PCT/US2023/030521

§ 371 Date: Feb. 18, 2025

Related U.S. Application Data
(60) Provisional application No. 63/373,034, filed on Aug. 19, 2022.

(51) Int. Cl. H10P 72/00

(52) U.S. Cl. CPC H10P 72/0402

(57) ABSTRACT

This disclosure pertains to compact, mono-block manifolds for providing dual-channel gas delivery for semiconductor processing tools. Some such manifolds may be designed to have surface-mount flow component interfaces on opposite sides of the manifold so as to reduce the overall footprint of the manifold block.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Semiconductor processing tools typically require the supply of different reactant gases to wafer processing spaces located within one or more semiconductor processing chambers. Surface-mount valves and other surface-mount flow components are typically used to provide for flow control of the various gases used during semiconductor processing operations in such tools.

Discussed herein are various improvements to manifolds that may be used with surface-mount flow control components.

### SUMMARY

Details of one or more implementations of the subject matter described in this specification are set forth in the accompanying drawings and the description below. Other features, aspects, and advantages will become apparent from the description, the drawings, and the claims.

In some implementations, an apparatus may be provided that includes a manifold block having a set of at least five surface-mount flow component interfaces. The set of at least five surface-mount flow component interfaces (SMFCIs) may include a first SMFCI having a first center axis, a second SMFCI having a second center axis, a third SMFCI having a third center axis, a fourth SMFCI having a fourth center axis, and a fifth SMFCI having a fifth center axis. The first center axis may be parallel to, and coincident with, a first reference plane, and the fourth center axis may be parallel to, and coincident with, a second reference plane. The first SMFCI may be configured to mate with a first surface-mount flow component, the second SMFCI may be configured to mate with a second surface-mount flow component, the third SMFCI may be configured to mate with a third surface-mount flow component, the fourth SMFCI may be configured to mate with a fourth surface-mount flow component, and the fifth SMFCI may be configured to mate with a fifth surface-mount flow component. The manifold block may include a first passage extending between the first SMFCI and the second SMFCI, a second passage extending between the second SMFCI and the third SMFCI, a third passage extending between the fourth SMFCI and the fifth SMFCI, and the first through third passages may be fluidically isolated from one another within the manifold block.

In some implementations, the first through fifth SMFCIs may be located on a same side of the manifold block.

In some implementations, the first SMFCI may be located on an opposite side of the manifold block from the second SMFCI.

In some such implementations, the second SMFCI and the third SMFCI may be on the same side of the manifold block.

In some implementations, the first passage may extend along a first passage axis that is perpendicular to a second passage axis along which the second passage extends, and the first passage axis may be perpendicular to the first SMFCI.

In some implementations, the first passage may be a straight passage.

In some implementations, the second and third center axes may be parallel to, and coincident with, the first reference plane.

In some implementations, the fifth center axis may be parallel to, and coincident with, the second reference plane.

In some implementations, the first reference plane may be parallel to the second reference plane.

In some implementations, the manifold block may further include a cross-passage that is internal to the manifold block and that fluidically connects the third SMFCI with the fifth SMFCI.

In some implementations, the manifold block may be connected with a cross-passage that is external to the manifold block and that fluidically connects the third SMFCI with the fifth SMFCI.

In some implementations, the apparatus may further include an outlet flow path segment, the outlet flow path segment having a first end fluidically connected with the cross-passage and a second end configured to connect with one or more components of a gas distribution system of a semiconductor processing tool.

In some implementations, the apparatus may further include a first inlet flow path segment and a second inlet flow path segment. The first inlet flow path segment may be fluidically connected with the first SMFCI, the second inlet flow path segment may be fluidically connected with the fourth SMFCI, and the first inlet flow path segment and the second inlet flow path segment may be fluidically isolated from each other.

In some implementations, the first inlet flow path segment may extend through a first side of the manifold block spanning between the side of the manifold block having the first SMFCI and a side of the manifold block opposite the side of the manifold block having the first SMFCI, and the second inlet flow path segment may extend through a second side of the manifold block spanning between the side of the manifold block having the first SMFCI and a side of the manifold block opposite the side of the manifold block having the first SMFCI.

In some implementations, the first inlet flow path segment and the second inlet flow path segment may both extend through a first side of the manifold block spanning between the side of the manifold block having the first SMFCI and a second side of the manifold block opposite the side of the manifold block having the first SMFCI.

In some implementations, the manifold block may have a width in a first direction perpendicular to the first reference plane that is 225% or less of widths of the SMFCIs in the first direction, and the manifold block may have a length in a second direction parallel to the first reference plane that is 300% or less of lengths of the SMFCIs in the second direction.

In some implementations, the set of at least five SMFCIs may include a sixth SMFCI, the manifold block may further include a fourth passage extending between the fifth SMFCI and the sixth SMFCI, and the sixth SMFCI may be fluidically isolated from the first through fifth SMFCIs within the manifold block.

In some implementations, the apparatus may further include the first, second, third, fourth, and fifth surface-mount flow components, as well as a sixth surface-mount flow component. The first surface-mount flow component may be connected with the first SMFCI, the second surface-mount flow component may be connected with the second SMFCI, the third surface-mount flow component may be connected with the third SMFCI, the fourth surface-mount flow component may be connected with the fourth SMFCI, the fifth surface-mount flow component may be connected with the fifth SMFCI, and the sixth surface-mount flow component may be connected with the sixth SMFCI.

In some such implementations, the first and fourth surface-mount flow components may be filters and the second, third, fifth, and sixth surface-mount flow components may be valves.

In some implementations, the first SMFCI may include four first holes arranged in a circular pattern about the first center axis, a first center port located along the first center axis, and at least a first off-center port located radially outward of the first center port with respect to the first center axis, the second SMFCI may include four second holes arranged in a circular pattern about the second center axis, a second center port located along the second center axis, and at least a second off-center port located radially outward of the second center port with respect to the second center axis, the third SMFCI may include four third holes arranged in a circular pattern about the third center axis, a third center port located along the third center axis, and at least a third off-center port located radially outward of the third center port with respect to the third center axis, the fourth SMFCI may include four fourth holes arranged in a circular pattern about the fourth center axis, a fourth center port located along the fourth center axis, and at least a fourth off-center port located radially outward of the fourth center port with respect to the fourth center axis, and the fifth SMFCI may include four fifth holes arranged in a circular pattern about the fifth center axis, a fifth center port located along the fifth center axis, and at least a fifth off-center port located radially outward of the fifth center port with respect to the fifth center axis.

The first center port and the first off-center port may each include a corresponding first bore and a corresponding first counterbore having a larger diameter than, and centered on, the corresponding first bore, the second center port and the second off-center port may each include a corresponding second bore and a corresponding second counterbore having a larger diameter than, and centered on, the corresponding second bore, the third center port and the third off-center port may each include a corresponding third bore and a corresponding third counterbore having a larger diameter than, and centered on, the corresponding third bore, the fourth center port and the fourth off-center port may each include a corresponding fourth bore and a corresponding fourth counterbore having a larger diameter than, and centered on, the corresponding fourth bore, and the fifth center port and the fifth off-center port may each include a corresponding fifth bore and a corresponding fifth counterbore having a larger diameter than, and centered on, the corresponding fifth bore.

### BRIEF DESCRIPTION OF THE DRAWINGS

Reference to the following Figures is made in the discussion below; the Figures are not intended to be limiting in scope and are simply provided to facilitate the discussion below.

FIG. 1 depicts an example flow component assembly.

FIG. 2 depicts the example flow component assembly of FIG. 1 in a partially exploded view.

FIG. 3 depicts an isometric view of a surface-mount flow component interface.

FIGS. 4 and 5 depict top and bottom isometric views of an example manifold block and some connected parts.

FIGS. 6 and 7 depict top and side views of the example manifold block of FIGS. 4 and 5 with section lines added to indicate section planes for FIGS. 8 through 10.

FIG. 8 is a section view along section line 8 in FIG. 7.

FIG. 9 is a section view along section line 9 in FIG. 6.

FIG. 10 is a section view along section lines 10 in FIG. 6.

FIGS. 11 and 12 depict top and bottom isometric views of another example manifold block and some connected parts.

FIG. 13 depicts a side view of the example manifold block of FIGS. 11 and 12 with section lines indicating section planes for section views 14 through 16.

FIG. 14 depicts a section view along line 14 in FIG. 13.

FIG. 15 depicts a section view along line 15 in FIG. 13.

FIG. 16 depicts a section view along line 16 in FIG. 13.

FIG. 17 depicts an isometric view of a flow component assembly using the example manifold block of FIGS. 11 through 16.

FIG. 18 depicts a section view of a variant of the manifold block of FIGS. 1 through 10.

FIG. 19 depicts an example of a prior art flow component assembly.

FIGS. 20 through 24 depict diagrams of various manifold block designs.

FIG. 25 depicts an example semiconductor processing system with flow component assemblies as discussed herein.

The above-described Figures are provided to facilitate understanding of the concepts discussed in this disclosure, and are intended to be illustrative of some implementations that fall within the scope of this disclosure, but are not intended to be limiting-implementations consistent with this disclosure and which are not depicted in the Figures are still considered to be within the scope of this disclosure.

### DETAILED DESCRIPTION

As noted earlier, the provisioning of reactant and other gases to a semiconductor processing chamber typically involves the use of multiple, often dozens, of valves between the sources of such gases and the processing chamber(s) to which they are delivered. In most semiconductor processing chambers, such gases are delivered from showerheads or gas distributors positioned above a pedestal within the chamber such that gases flowed out of the showerhead or gas distributor flow across the pedestal and a wafer supported thereby. In most cases, many of the valves and other flow control components used may be mounted in what is referred to as a “gas box” in the industry—a large enclosure that may house multiple sets of flow control components, one set for each of several different gases, that may be controlled so as to produce a desired gas flow that is then delivered to a semiconductor processing chamber.

There may also, however, be some valves or other flow-control components that are located directly adjacent the exterior of the semiconductor processing chamber near where the gases are to be delivered, thereby reducing or minimizing the distance that the gases flowed therethrough must travel before reaching the wafer. Such valves or other flow-control components may be referred to herein as “point-of-use” valves or flow-control components. Point-of-use valves and flow-control components provide enhanced control of the timing of when such gas flows reach the wafer and potentially reduce the amount of gas that may be wasted during such flows (by reducing the lag time between when a particular gas flow to the chamber is turned off or adjusted and when the effects of such adjustment are evident in the gas flow reaching the wafer). In some semiconductor processing tools, it may also be desirable to mix two or more reactants together to form a compound that is more reactive, e.g., two reactants that by themselves do not form a deposition layer but that do form a deposition layer when combined into a particular compound. In such tools, it may be desirable to mix the two or more reactants together close to the delivery point so that there is reduced or minimal exposure of the gas delivery lines and components to the compound formed thereby (thereby reducing the potential for deposition in the gas supply lines/components or other undesired interaction of the compound with the gas supply lines/components).

In typical semiconductor processing tools where the showerheads or gas distribution systems are positioned above the pedestals, point-of-use valve and flow-control component assemblies for controlling gas flows at locations proximate the showerhead or gas distributor may be mounted, in some cases, directly to the top plate or lid of the chamber to which gas is being delivered. Such a location may, in many cases, be generally free of large, bulky equipment and may typically be relatively easy to access for maintenance purposes.

In some semiconductor processing tools, however, reactants may be delivered to the underside of a wafer. In such tools, the pedestal may, in effect, be an upside-down showerhead or gas distributor, and the wafer may actually be supported by a ring or support columns at a location above the pedestal, thereby forming a gap between the wafer and the pedestal. In such tools, point-of-use valves and flow-control components may instead need to be mounted beneath the chamber(s) to which process gases are to be delivered. There is, however, typically much less flexibility in terms of mounting locations for such equipment on the underside of processing chambers. For example, in many semiconductor processing tools, there may be large-diameter exhaust conduits, vertical drive systems for moving pedestals up and down, high-voltage electrical feeds for providing radio-frequency power to electrodes within the chamber, and support structures for supporting the chambers that are located beneath the chambers. Additionally, there may be clearance requirements that need to be met in order to provide sufficient access to the various systems located beneath the chambers for maintenance purposes. These issues make it challenging to find room for point-of-use valves and flow-control components underneath processing chambers.

The present inventor conceived of a compact, dual-channel, monoblock manifold for surface-mount valves and flow-control components that allows for two separate input streams to be filtered and controlled with valves prior to being combined into one common outlet flow path. Such manifolds have a compact packaging footprint that makes them more suited for mounting in space-constrained locations, e.g., underneath semiconductor processing chambers. At the same time, such manifolds, by virtue of their “monoblock” design, may also have a reduced number of potential leak points, thereby reducing the possibility of leaks and the potential need for maintenance/refit.

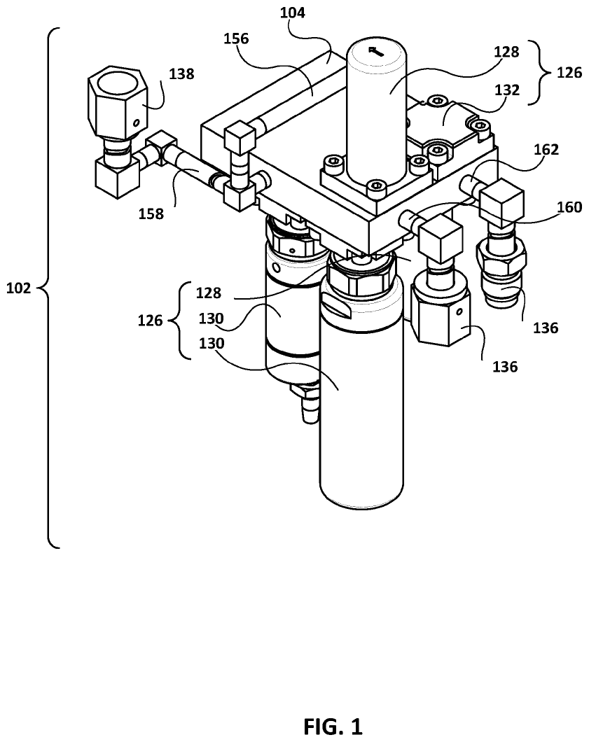

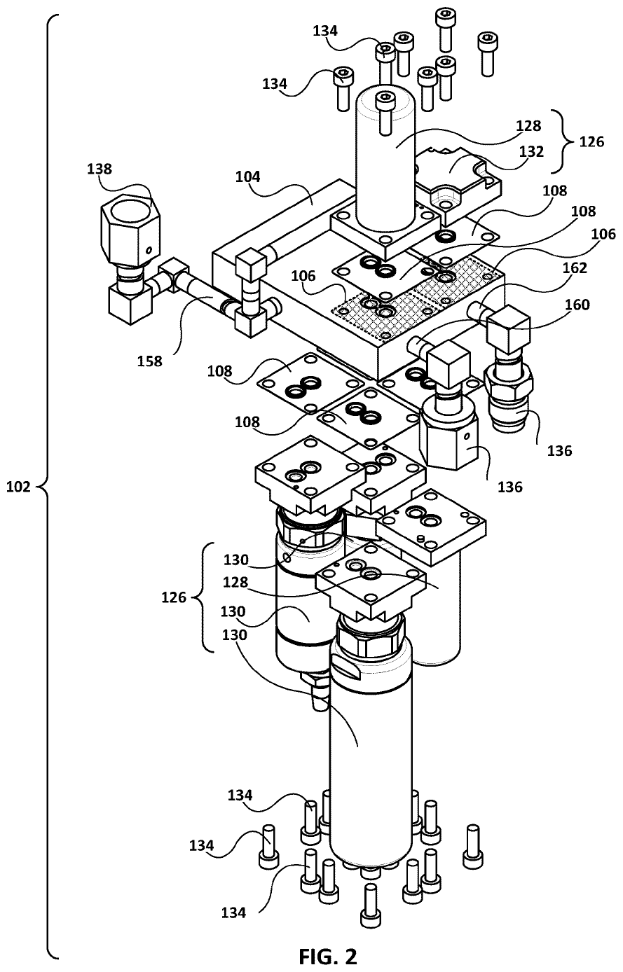

FIG. 1 depicts an example point-of-use flow component assembly that utilizes such a dual-channel monoblock manifold. FIG. 2 depicts the example point-of-use flow component assembly in a partially exploded state. As shown in FIGS. 1 and 2, a flow component assembly 100 is provided by mounting surface-mount flow components 126, e.g., filters 128, valves 130, etc., to a manifold block 104 using fasteners 134. Each surface-mount flow component may mate with a corresponding surface-mount flow component interface (SMFCI) 106 on the manifold block 104. The surface-mount flow components may include, for example, valves, filters, pressure regulators, pass-through caps (which may be used when the number of SMFCIs that are provided for a particular channel in the manifold block 104 is greater than the number of flow components that are needed for that channel), etc.

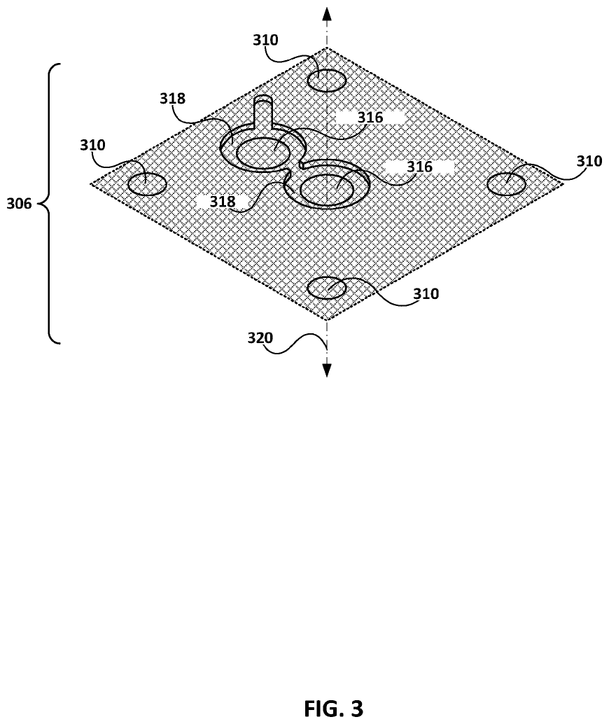

SMFCIs are industry-standard fluidic interfaces that allow for a modular approach to assembling fluidic control systems; they are commonly used in the semiconductor processing field and there are a wide variety of different types of flow components that are offered by different manufacturers that all use SMFCIs. FIG. 3, which is a to-scale drawing, depicts an isometric view of a typical SMFCI 306. As can be seen the SMFCI 306 is a square region, e.g., ~1.125 inches on a side, with a circular or square pattern of holes 310 centered on a center axis 320 of the SMFCI 306. The holes 310 may be through-holes to allow threaded fasteners to be inserted therethrough in order to secure a surface-mount flow component thereto, e.g., using nuts threaded onto the threaded ends of the fasteners. Alternatively, the holes 310 may be threaded such that the fasteners may be screwed directly into the threaded holes 310. It will be evident that due to the radially symmetric arrangement of the square region and the holes 310 about the center axis 320, a surface-mount flow component may generally be mated with an SMFCI 306 in any one of four possible orientations, each 90° apart from the adjacent orientations. The SMFCI 306 may also include bores 316, each of which may lead to a separate flow path internal to the component having the SMFCI 306. One of the bores 316 is generally centered on the center axis 320 such that it aligns with a corresponding opening on a surface-mount flow component regardless of orientation of that surface-mount flow component. One or more additional bores 316 may be provided at locations that are radially offset, with respect to the center axis 320, from the center-located bore 316. Each bore 316 may be provided with a counterbore 318 that may be sized so as to house an annular seal, e.g., an O-ring or C-seal. In FIG. 3, only two bores 316 for the depicted SMFCI 306 are shown, but other SMFCIs 306 may have three, four, or five bores 316 (some later examples herein shown SMFCIs with three bores 316).

Fluids that flow through an SMFCI 306 typically flow into the flow component mated to the SMFCI 306 through one of the bores 316 and then flow out of the flow component via the other bore or bores 316. SMFCIs 306 are generally planar in nature as they are designed to mate against a flat flange on the flow component.

Returning to FIGS. 1 and 2, the manifold block 104 shown has a total of six SMFCIs 106—two on the top side (visible in FIG. 2), and four on the bottom side (not visible in FIG. 2). The manifold block 104 also has attached thereto a pair of inlet fittings 136 and an outlet fitting 138. Each inlet fitting 136 fluidically connects with a corresponding inlet flow path segment that leads to one of the SMFCIs 106. Similarly, the outlet fitting 138 fluidically connects with an outlet flow path segment that leads to two of the SMFCIs 106, e.g., via cross-passage 156.

As can be seen, optional seal plates 108 may be sandwiched between each flow component 126 and the SMFCI 106 that it is mounted to. Each seal plate 108 may, for example, take the form of a thin, metal square of the same size and shape as the SMFCI and which has through-holes that correspond in location to the various holes and bores of the SMFCI 106. The holes that correspond in location with the bores of the SMFCI may be equipped with C-seals, e.g., metal, tubular toroids having a circumferential slit along their outermost circumference—the hole for each such bore may be sized slightly smaller than the C-seal such that the C-seal traps the metal square within the circumferential slit, thereby retaining the C-seals in the seal plates 108. The seal plates 108 may allow the seals retained therein to be easily and simultaneously positioned within the SMFCI 106 with which they are used and may reduce the chance of losing one of the seals during installation.

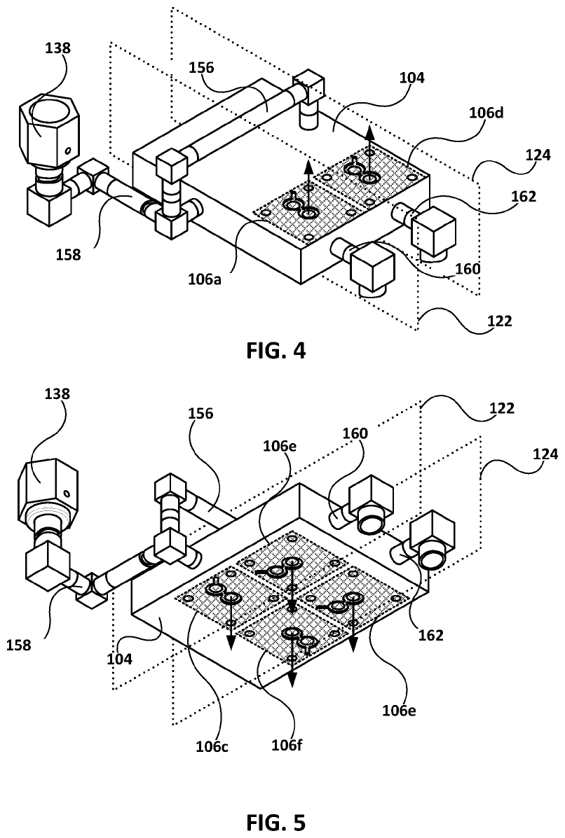

FIGS. 4 and 5 depict isometric views of the manifold block 104 without the flow components 126 attached. All six SMFCIs 106 are visible in FIGS. 4 and 5 (the center axes of the SMFCIs 106 are represented in the Figures by arrows that are normal to each SMFCI 106). Also visible in FIGS. 4 and 5 are a first inlet flow path segment 160 and a second inlet flow path segments 162, each of which would fluidically connect one of the inlet fittings 136 (omitted in these views) with a corresponding one of the SMFCIs 106. For reference, the SMFCIs 106 in FIGS. 4 and 5 have been sub-designated as SMFCIs 106a/b/c/d/e/f, and may be referred to herein as first/second/third/fourth/fifth/sixth SMFCIs, respectively. Thus, for example, the first inlet flow path segment 160 may fluidically connect with one of the ports of the first SMFCI 106a and the second inlet flow path segment 162 may fluidically connect with one of the ports of the fourth SMFCI 106d. An outlet flow path segment 158 may also be provided to fluidically connect the outlet fitting 138 to two of the SMFCIs 106, e.g., via cross-passage 156.

Also shown in FIGS. 4 and 5 are a first reference plane 122 and a second reference plane 124. In this example, the first reference plane 122 and the second reference plane 124 are parallel to one another, although in other implementations, non-parallel arrangements of the first reference plane 122 and the second reference plane 124 may occur. Further reference to these reference planes will be made in the discussion below.

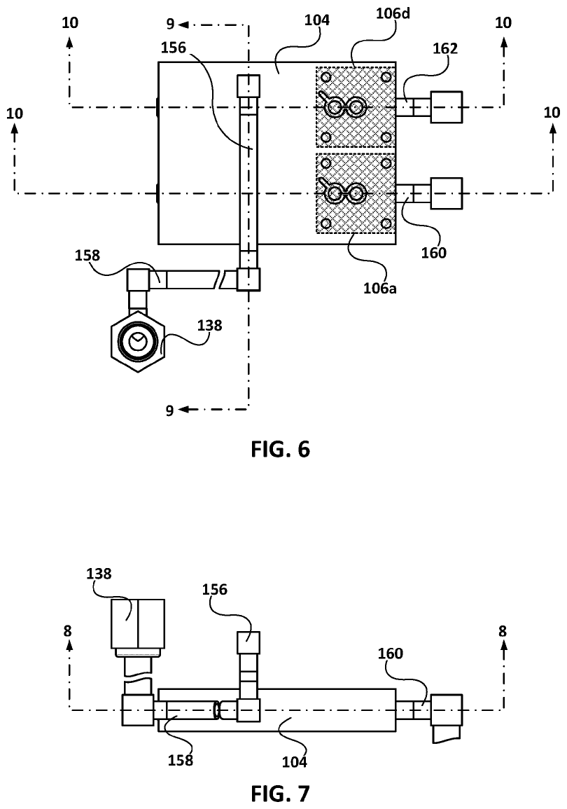

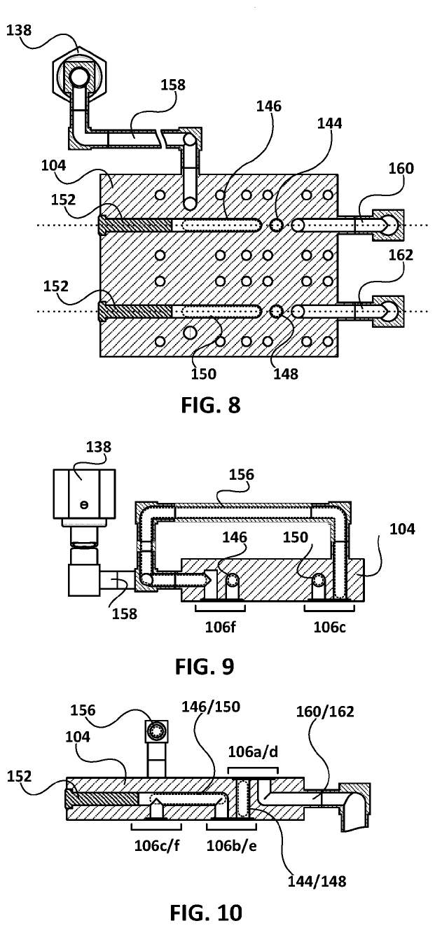

FIGS. 6 and 7 depict top and side views of the manifold block 104 (and some connected hardware) with section lines indicating the section planes for FIGS. 8 through 10. Thus, FIG. 8 is a section view of the manifold block 104 (and some connected hardware) through the section line of FIG. 7, FIG. 9 is a section view of the manifold block 104 and cross-passage 156 through the vertical section line of FIG. 6, and FIG. 10 is a section view of the manifold block 104 through either of the horizontal section lines of FIG. 6 (in this example, both sections are the same).

As can be seen in FIG. 8, the manifold block 104 may have two flow paths from the first inlet flow path segment 160 and the second inlet flow path segment 162 that are fluidically isolated from one another within the manifold block 104 at least up until the point where the fluid flows have exited the last of the SMFCIs 106. The first flow path, for example, may begin with the first inlet flow path segment 160 and flow through the first SMFCI 106a. The first flow path may further include a first passage 144 (in this case, a straight passage that extends through the manifold block 104 in a direction perpendicular to the first SMFCI 106a (e.g., along the center axis of the first SMFCI 106a); see FIG. 10) that fluidically connects the first SMFCI 106a with the second SMFCI 106b. A second passage 146 that is part of the first flow path may similarly fluidically connect the second SMFCI 106b with the third SMFCI 106c. The second passage 146 may, for example, be provided by a hole that is drilled into one end of the manifold block 104, past the third SMFCI 106c, and to the second SMFCI 106b. A plug 152 may then be inserted into the drilled hole and welded or brazed into place to seal the drilled hole. The plug 152 may, for example, extend to a depth in the drilled hole that is less than the depth at which the drilled hole may fluidically connect with the third SMFCI 106c.

In a similar manner, the second flow path may begin with the second inlet flow path segment 162 and flow through the fourth SMFCI 106d. The second flow path may further include a third passage 148 that fluidically connects the fourth SMFCI 106d with the fifth SMFCI 106e within the manifold block 104, and a fourth passage 150 that fluidically connects the fifth SMFCI 106e with the sixth SMFCI 106f within the manifold block. In this example, the first passage 144 and the second passage 146 are both straight passages with center axes that lie on, e.g., are coincident with and parallel to, the first reference plane 122, and the third passage 148 and the fourth passage 150 are both straight passages with center axes that lie on the second reference plane 124. In the depicted arrangement, the sections of the first and second flow paths that include the first through fourth passages 144 through 150 are generally duplicates of one another (including the plugs 152) and thus should have similar or identical gas flow characteristics.

In the example of the manifold block 104, the two flow paths remain fluidically isolated from one another within the manifold block 104 at all times, but are then fluidically connected with one other via the cross-passage 156 (see FIG. 9), which is provided by a welded tube structure that is welded or brazed to the manifold block 104. The cross-passage 156 is fluidically connected with the outlet flow path segment 158, thereby allowing gases delivered through both flow paths to be delivered in a combined fashion from the outlet flow path segment 158.

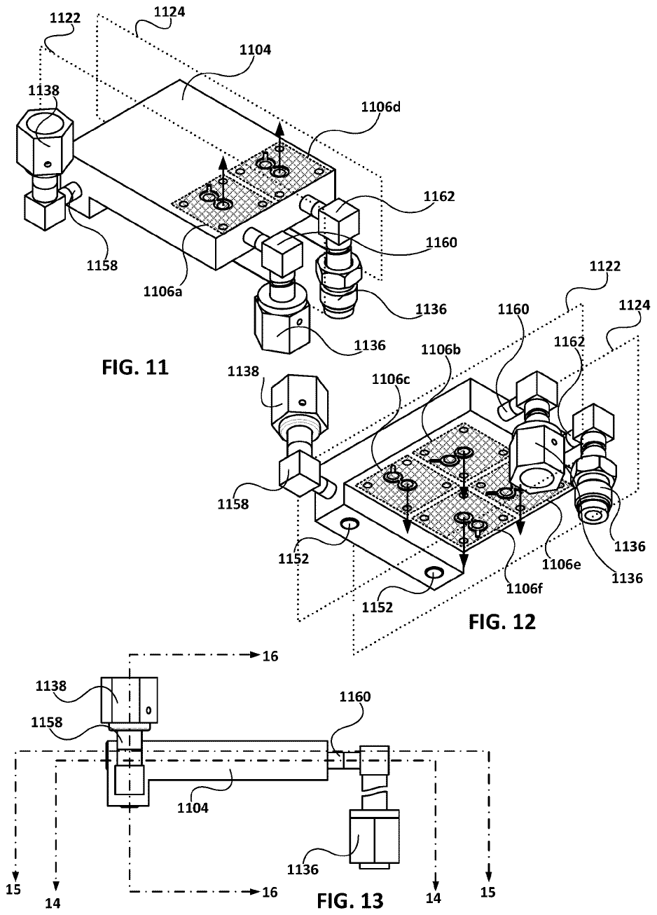

An alternate implementation of the manifold block 104 is shown in FIGS. 11 and 12, which are top and bottom isometric views of a manifold block 1104. The manifold block 1104, similar to the manifold block 104, is connected with inlet fittings 1136 via a first inlet flow path segment 1160 and a second inlet flow path segment 1162 and with outlet fitting 1138 via an outlet flow path segment 1158. The manifold block 1104 may also have associated with it a first reference plane 1122 and a second reference plane 1124. SMFCIs 1106a-f are also depicted. The cross-passage is also present in this design, but is incorporated into the manifold block 1104, e.g., in the raised portion thereof in which plugs 1152 are visible in FIG. 12.

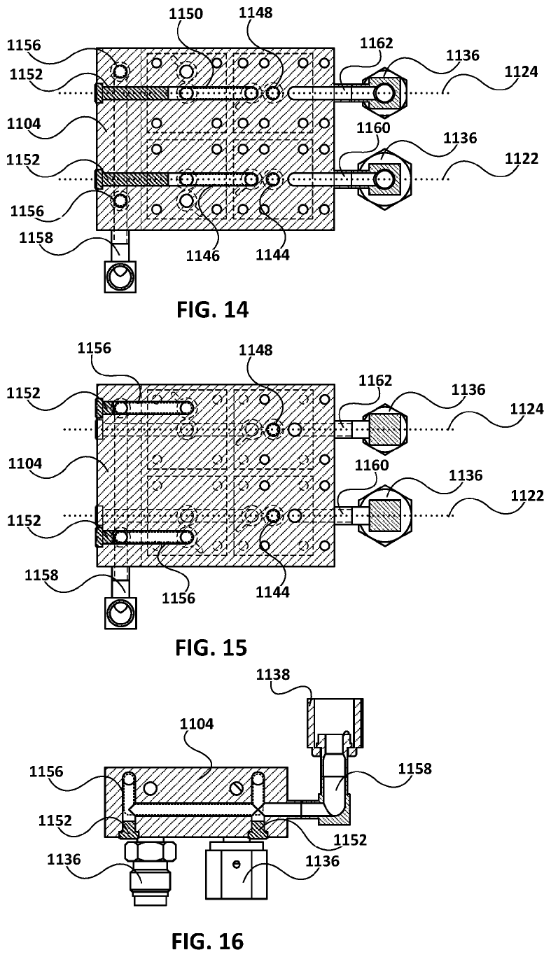

FIG. 13 depicts a side view of the manifold block 1104 (and some additional components) with section lines indicating the section planes for FIGS. 14 through 16. As is evident from FIG. 14, the first through fourth passages 1144 through 1150, respectively, between the SMFCIs 1106a-f are generally arranged in an identical manner to the first through fourth passages 144 through 150 of the manifold block 104. However, as is evident from FIGS. 15 and 16, the manifold block 1104 differs from the manifold block 104 in that the manifold block 1104 incorporates an internal cross-passage 1156. The cross-passage 1156 in this example makes several turns—first extending along short passages leading from the ports for the third SMFCI 1106c and the sixth SMFCI 1106f to short riser passages (extending along directions perpendicular to the SMFCIs 1106) that extend from those short passages to a crossover segment that links the two riser passages. The outlet flow path segment 1158 may fluidically connect with the cross-passage 1156, e.g., via a connection to a hole in the side of the manifold block 1104 that leads to the cross-passage 1156. This design eliminates some of the external flow components, e.g., elbows and tube segments, that the manifold block 104 is connected with in order to provide the cross-passage 156, and may thus be less susceptible to damage (although perhaps requiring more machining/material for the manifold block 1104).

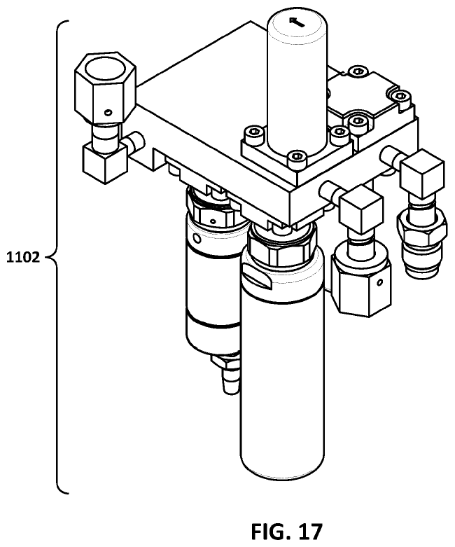

FIG. 17 shows the manifold block 1104 with various flow components attached to form a flow component assembly 1102, similar to FIG. 1. As can be seen, the two manifold blocks 104 and 1104 generally occupy the same packaging volume.

It will be appreciated that in the examples discussed above, each of the two flow paths into the manifold blocks 104 and 1104 may pass through three different SFMCIs in series. This allows a variety of different configurations of surface-mount flow components to be mounted to the manifold block in order to provide different functionality. For example, in some implementations, surface-mount filters may be installed in the SMFCIs that are closest to the first and second inlet flow path segments, thereby allowing filtration of the process gases supplied therethrough just prior to reaching the semiconductor processing chamber. In such implementations, one or two surface-mount valves may be installed immediately downstream thereof. For example, a shut-off valve (e.g., one that can rapidly be switched between fully open and fully closed, but which may not be capable of more granular flow control) may be installed at one or both of the second and fifth SMFCIs, while a flow-rate-control valve, e.g., one that can be switched between at least two different non-zero flow rates, may be installed at one or both of the third and sixth SMFCIs. Such configurations may allow for either variable or single-speed flow control of gas flowing along each flow path.

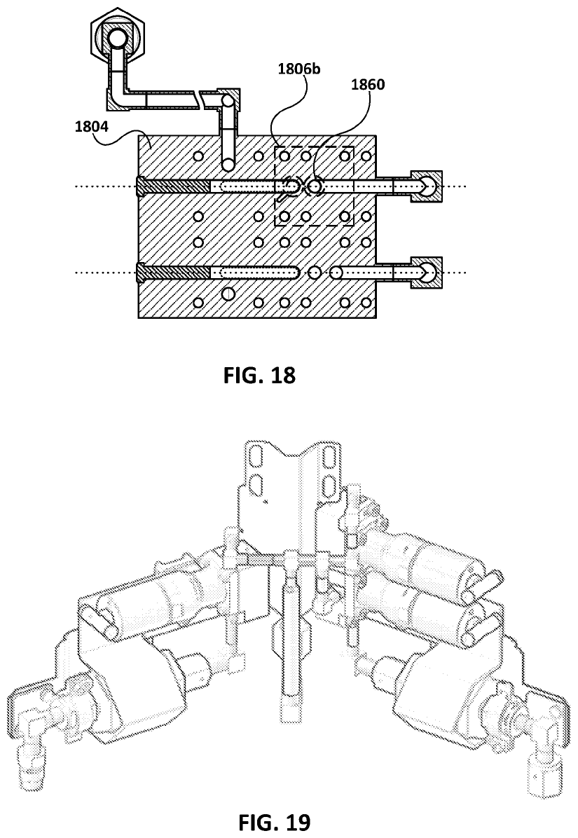

It will be further appreciated that if a flow control component is omitted from an SMFCI, e.g., as is the case in the above examples for the fourth SMFCI, a pass-through cap, e.g., such as pass-through cap 132, may be used to route gas through that SMFCI with a low or minimal increase in flow resistance. Alternatively, the manifold block may be designed with one of the SMFCIs on either or both flow paths being entirely omitted, in which case there may be a lesser number of passages between SMFCIs. For example, as shown in FIG. 18, a manifold block 1804 is shown that is identical to the manifold block 104 except that the first SMFCI 106a has been omitted. The first inlet flow path segment 1860 has been extended to reach the bore of the second SMFCI 1806b, thereby providing an equivalent to if the pass-through cap were to be used (although a more-streamlined equivalent).

Additionally, while the SMFCIs shown in the accompanying Figures are all of the same size, it will be appreciated that there may be different sizes of SMFCIs used in different contexts, and that the manifold blocks discussed herein may use a mix of different sizes of SMFCIs.

It will be apparent from the above discussion and the Figures discussed therein that the manifold block of the above examples provides for a very compact valve system. As compared with a prior system, e.g., such as is shown in FIG. 19, the examples provided above were found to offer about a 72% reduction in packaging envelope size—allowing two such manifold block assemblies to be fit within the same volume occupied by one equivalent valve system as shown in FIG. 19. To give an idea of scale, some manifold blocks like those discussed above may have a width in a first direction perpendicular to the first reference plane that is less than 225%, e.g., between 200% and 225%, of the width of one of the SMFCIs in the first direction, and a length in a second direction parallel to the first reference plane and perpendicular to the first direction that is less than 300%, e.g., between 230% and 300%, of the width of one of the SMFCIs in the first direction. For example, the implementation shown in FIGS. 1 through 10 may (excluding the inlet and outlet flow path hardware extending from the manifold block 104) have a height in a direction parallel to the SMFCI center axes that is on the order of less than 8″, a width in a direction perpendicular to the first reference plane that is on the order of 2.5″, and a length in a direction parallel to the SMFCIs and perpendicular to the width direction that is on the order of 3.375″.

Such a compact footprint is, in part, facilitated by the location of some of the SMFCIs on opposite sides of the manifold blocks. This allows the SMFCIs to overlap in footprint when viewed along the SMFCI center axes, thereby allowing an increased number of SMFCIs to be fit within a given area (as compared with an arrangement of SMFCIs in which all of the SMFCIs are to be arranged in a non-overlapping manner. It will be appreciated that such overlap is not strictly necessary—although a manifold block in which all of the SMFCIs are on the same side, without overlap, may be unable to be used to provide quite as compact an assembly as the depicted valve assemblies.

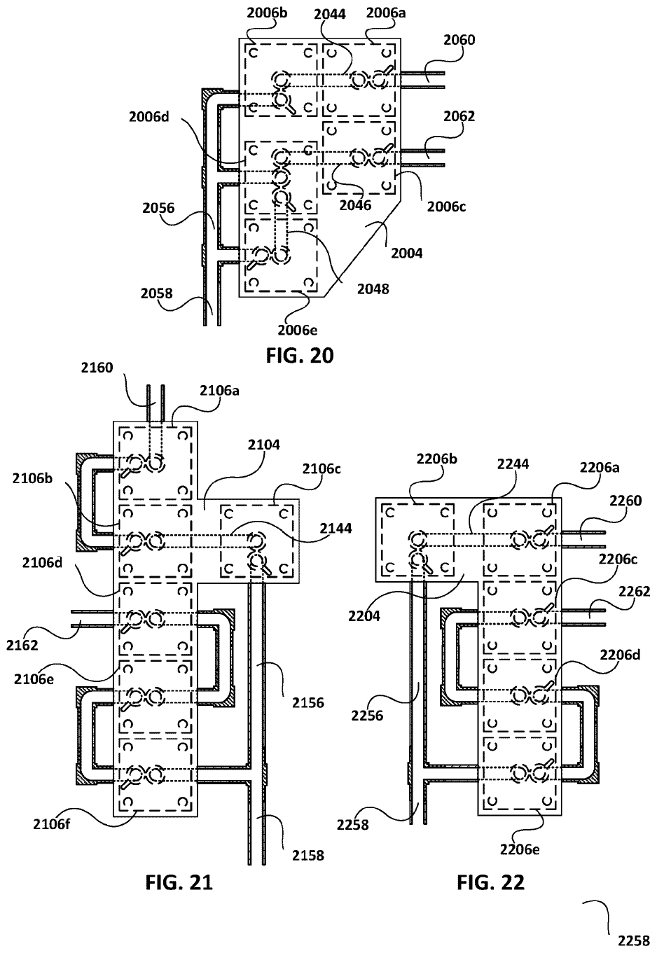

Alternative arrangements of manifold blocks that may provide similar, although perhaps not as space-efficient, reduced packaging volumes (with non-overlapping SMFCI footprints) are shown in FIGS. 20 through 24. In FIGS. 20 through 24, SMFCIs are shown in dashed broken lines while passages internal to the manifold blocks, e.g., between ports of SMFCIs or between an SMFCI port and an external tubular passage, elbow fitting, or T-fitting, are shown in dotted broken lines.

In FIG. 20, a manifold block 2004 is shown that has an arrangement of five SMFCIs on it—the SMFCIs 2006a and 2006b may be fluidically connected in series with a first inlet flow path 2060, thereby allowing a first surface-mount flow component, e.g., a filter, to be mounted to the first SMFCI 2006a and a second surface-mount flow component, e.g., a valve, to be mounted to the second SMFCI 2006b, thereby allowing the flow of filtered gas to a cross-passage 2056 leading to an outlet flow path segment 2058 to be controlled. A second inlet flow path 2062 may be fluidically connected, in series, with a third SMFCI 2006c, a fourth SMFCI 2006d, and a fifth SMFCI 2006e. The fourth SMFCI 2006d and the fifth SMFCI 2006e may also be fluidically connected with the cross-passage 2056 such that gas flowing through either or both of the fourth SMFCI 2006d and the fifth SMFCI 2006e will mix with the gas flowed into the cross-passage 2056 from the second FMFCI 2006b. As can be seen, the first SMFCI 2006a is fluidically connected with the second SMFCI 2006b by a first passage 2044, while the third SMFCI 2006c is fluidically connected with the fourth SMFCI 2006d by a second passage 2046. The first passage 2044 and the second passage 2046 may, for example, extend along parallel directions and be of generally the same length. A third passage 2048 may fluidically connect the fourth SMFCI 2006d with the fifth SMFCI 2006e; the third passage 2048 may, for example, extend along a direction perpendicular to the first passage 2044 and the second passage 2046 and parallel to the SMFCIs 2006.

The manifold block 2004 provides a compact assembly that is nearly as compact in the plane of the SMFCIs as that shown above with respect to the manifold blocks 104 and 1104, but which is also more compact in the direction perpendicular to the SMFCIs. It will also be observed that the second flow path in the manifold block 2004 has two fluidic connection points with the cross-passage 2056, as opposed to the single fluidic connection point of the second flow path with the cross-passages 156 or 1156 of the manifold blocks 104 or 1104, respectively. The SMFCI 2006d is, in this example, a 3-port SMFCI—when connected with a surface-mount diaphragm valve, for example, the valve may be operated to close off the center port from the two flanking ports (which may remain fluidically connected due to a toroidal plenum surrounding the sealed center port). In this case, one of the flanking ports in the SMFCI 2006d may be connected with the second passage 2046, thereby supplying gas to the second flanking port in the SMFCI 2006d, and thus to the SMFCI 2006e, regardless of the valve state of the valve connected with the SMFCI 2006d. When the valve at the SMFCI 2006d is actuated to an open state, gas can be directed to the cross-passage 2056 via the center port of the SMFCI 2006d. Similarly, when a valve at the SMFCI 2006e is actuated to an open state, gas can be directed to the cross-passage 2056 via one of the ports of the SMFCI 2006e. If, for example, the two flow paths leading to the cross-passage 2056 from the SMFCIs 2006d and 2006e are caused to have different flow resistances, e.g., through the use of one or more flow restrictors or restrictions that may be fluidically interposed between the cross-passage 2056 and one or both of the SMFCIs 2006d and 2006e, this may, in effect, allow the flow through the SMFCIs 2006d and 2006e to be switched between two or three different flow rates (e.g., through a lower-flow rate flow path from one of the SMFCIs 2006d and 2006e, through a higher-flow rate flow path from the other of the SMFCIs 2006d and 2006e, or through both flow paths from the SMFCIs 2006d and 2006e).

FIG. 21 depicts a manifold block 2104 is shown that has an arrangement of six SMFCIs on it—the SMFCIs 2106a, 2106b, and 2106c may be fluidically connected in series with a first inlet flow path 2160, thereby allowing a first surface-mount flow component, e.g., a filter, to be mounted to the first SMFCI 2106a and a second and third surface-mount flow components, e.g., valves, to be mounted to the second SMFCI 2106b and the third SMFCI 2106c, thereby allowing the flow of filtered gas to a cross-passage 2156 leading to an outlet flow path segment 2158 to be controlled. A second inlet flow path 2162 may be fluidically connected, in series, with a fourth SMFCI 2106d, a fifth SMFCI 2106e, and a sixth SMFCI 2106f. The sixth SMFCI 2106f may also be fluidically connected with the cross-passage 2156 such that gas flowing through the sixth SMFCI 2106f will mix with the gas flowed into the cross-passage 2156 from the third FMFCI 2106c. As can be seen, the second SMFCI 2106b is fluidically connected with the third SMFCI 2106c by a first passage 2144, while the first SMFCI 2106a is fluidically connected with the second SMFCI 2106b by an external fluid passage, e.g., provided by tubes and elbow fittings, that are external to the manifold block 2104. A filter may, for example, be connected with the fourth SMFCI 2106d, while valves may be connected with the fifth SMFCI 2106e and the sixth SMFCI 2106f. The two valves in series may, for example, include an upstream shut-off valve and a downstream variable flow rate valve.

The fourth SMFCI 2106d and the fifth SMFCI 2106e, as well as the fifth SMFCI 2106e and the sixth SMFCI 2106f, are also fluidically connected via exterior fluid passages in this example. Also in this example, five of the SMFCIs lie along a common axis, e.g., in a linear array, but with the directions of the fluid flow through each of these SMFCIs (or at least portions of these SMFCIs) lying along directions perpendicular to the array axis.

FIG. 22 depicts a manifold block 2204 that is similar to the manifold block 2104 except that the first SMFCI 2106a is omitted, and the first flow path flows directly into what would be the second SMFCI 2106b of the manifold block 2104. Features of the manifold block 2204 that have callouts with the same last two digits as similar features in the manifold block 2104 may be assumed to be the same, and the description of those analogous features in the discussion of the manifold block 2104 above is equally applicable to the counterparts of those features in FIG. 22.

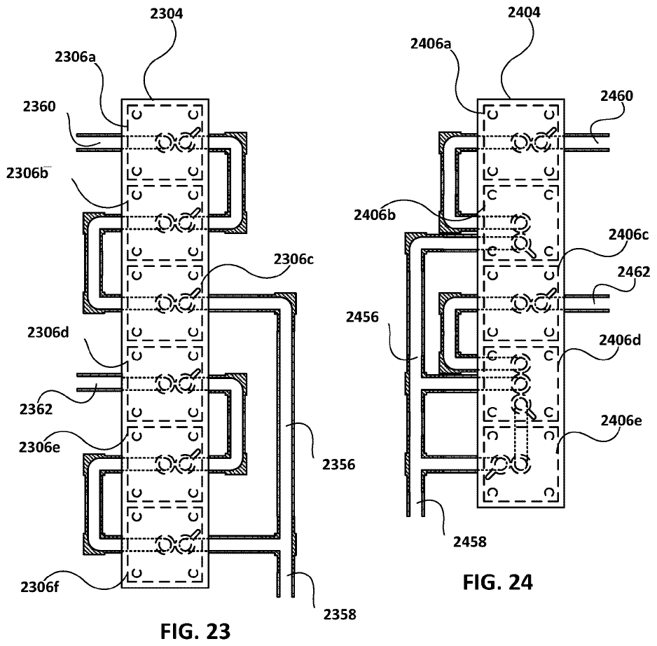

FIG. 23 depicts a manifold block 2304 similar to the manifold block 2104 except that all six of the SMFCIs 2306a-f are arranged in a linear array. There are also no passages internal to the manifold block 2304 that connect two SMFCIs-instead, the first SMFCI 2306a is fluidically connected with the second SMFCI 2306b by an external flow path and the second SMFCI 2306b is fluidically connected with the third SMFCI 2306c by another external flow path. Similarly, the fourth SMFCI 2306d is fluidically connected with the fifth SMFCI 2306e by an external flow path and the fifth SMFCI 2306e is fluidically connected with the sixth SMFCI 2306f by another external flow path. The third SMFCI 2306c and the sixth SMFCI 2306f are both fluidically connected with a cross-passage 2356 that leads to an outlet flow path segment 2358. Flow control components may be connected with the SMFCIs 2306a-f in a manner similar to how flow control components may be connected with the SMFCIs 2106a-f. Features of the manifold block 2304 that have callouts with the same last two digits as similar features in the manifold block 2104 may be assumed to be the same, and the description of those analogous features in the discussion of the manifold block 2104 above is equally applicable to the counterparts of those features in FIG. 23.

FIG. 24 depicts a manifold block 2404 that includes five SMFCIs 2406a-e which may provide a fluidic circuit similar in functionality and operation to that of FIG. 20, except with the SMFCIs 2406a-e in a linear array. Only one passage 2444 internal to the manifold block is provided in this example to fluidically connect the fourth SMFCI 2406d and the fifth SMFCI 2406e; the remaining fluidic connections between SMFCIs are accomplished via external tubing connections. Features of the manifold block 2404 that have callouts with the same last two digits as similar features in the manifold block 2104 may be assumed to be the same, and the description of those analogous features in the discussion of the manifold block 2104 above is equally applicable to the counterparts of those features in FIG. 24.

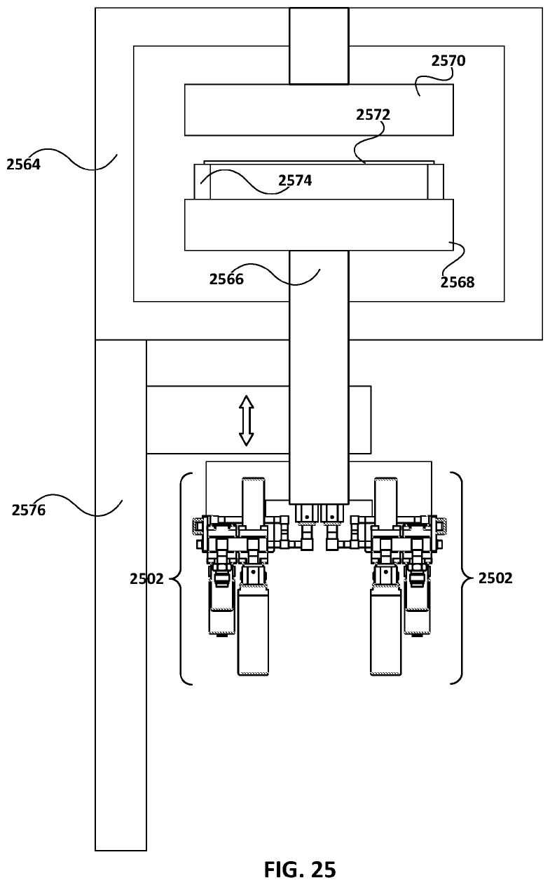

As noted above, the manifold blocks discussed herein, as well as the valve assemblies that use them, may be installed beneath a semiconductor processing chamber. FIG. 25 depicts an example of such an installation. In FIG. 25, a semiconductor processing chamber 2564 is shown that includes a showerhead 2570 that may be used to provide processing gas to a wafer 2572 that may be supported within the chamber 2564 by wafer supports 2574 that are connected with a shower-pedestal 2568. The shower-pedestal 2568 may have a plurality of orifices in the top surface that may be used to supply processing gas to the underside of the wafer 2572. The orifices may be provided gas via an internal plenum (not shown) of the shower-pedestal 2568 that is provided gas from flow component assemblies 2502, e.g., assemblies similar to flow component assembly 102, for example, via stem 2566. A lift mechanism 2576 may be provided to allow the stem 2566 (and the shower-pedestal 2568) to be moved up and down vertically within the chamber 2564, if desired. The flow component assemblies 2502 may be connected with the stem 2566 so that they move in tandem with the stem 2566.

The control of flow component assemblies such as are described herein may be facilitated through the use of a controller that may be included as part of a semiconductor processing tool having the flow component assemblies. The systems discussed above may be integrated with electronics for controlling their operation before and after processing of a semiconductor wafer or substrate. The electronics may be referred to as the “controller,” which may control various components or subparts of the system or systems. The controller, depending on the processing requirements and/or the type of system, may be programmed to control any of the systems disclosed herein, including operation of the various valves or other components that may be included in a flow control assembly.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular gas flow operations using the flow component assemblies described herein.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber, e.g., a VTM, in communication with one or more integrated circuits located remotely (such as at the platform level or as part of a remote computer) that combine to control a gas flow operation using a flow component assembly as discussed herein.

Without limitation, flow component assemblies as described herein may be connected with one or more other pieces of equipment, including a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, or any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers, e.g., FOUPs, to and from tool locations and/or load ports in a semiconductor manufacturing factory.

For the purposes of this disclosure, the term “fluidically connected” is used with respect to volumes, plenums, holes, etc., that may be connected with one another, either directly or via one or more intervening components or volumes, in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet. The term “fluidically adjacent,” if used, refers to placement of a fluidic element relative to another fluidic element such that there are no potential structures fluidically interposed between the two elements that might potentially interrupt fluid flow between the two fluidic elements. For example, in a flow path having a first valve, a second valve, and a third valve placed sequentially therealong, the first valve would be fluidically adjacent to the second valve, the second valve fluidically adjacent to both the first and third valves, and the third valve fluidically adjacent to the second valve.

The use, if any, of ordinal indicators, e.g., (a), (b), (c) . . . or (1), (2), (3) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”(4)It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items-it will be understood that a set or a subset can encompass only one member or multiple members (unless the context indicates otherwise).

The term “between,” as used herein and when used with a range of values, is to be understood, unless otherwise indicated, as being inclusive of the start and end values of that range. For example, between 1 and 5 is to be understood to be inclusive of the numbers 1, 2, 3, 4, and 5, not just the numbers 2, 3, and 4.

The term “operatively connected” is to be understood to refer to a state in which two components and/or systems are connected, either directly or indirectly, such that, for example, at least one component or system can control the other. For example, a controller may be described as being operatively connected with a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely cannot supply such power directly to the resistive heating unit due to the currents involved, but it will be understood that the controller is nonetheless operatively connected with the resistive heating unit.

It is understood that the examples and implementations described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein but may be modified within the scope of the disclosure.

It is to be understood that the above disclosure, while focusing on a particular example implementation or implementations, is not limited to only the discussed example, but may also apply to similar variants and mechanisms as well, and such similar variants and mechanisms are also considered to be within the scope of this disclosure.

1. An apparatus comprising:
a manifold block having a set of at least five surface-mount flow component interfaces, wherein:
the set of at least five surface-mount flow component interfaces (SMFCIs) includes a first SMFCI having a first center axis, a second SMFCI having a second center axis, a third SMFCI having a third center axis, a fourth SMFCI having a fourth center axis, and a fifth SMFCI having a fifth center axis,
the first center axis is parallel to, and coincident with, a first reference plane,
the fourth center axis is parallel to, and coincident with, a second reference plane,
the first SMFCI is configured to mate with a first surface-mount flow component, the second SMFCI is configured to mate with a second surface-mount flow component, the third SMFCI is configured to mate with a third surface-mount flow component, the fourth SMFCI is configured to mate with a fourth surface-mount flow component, and the fifth SMFCI is configured to mate with a fifth surface-mount flow component,
the manifold block includes a first passage extending between the first SMFCI and the second SMFCI, a second passage extending between the second SMFCI and the third SMFCI, a third passage extending between the fourth SMFCI and the fifth SMFCI, and
the first through third passages are fluidically isolated from one another within the manifold block.

2. The apparatus of claim 1, wherein the first through fifth SMFCIs are located on a same side of the manifold block.

3. The apparatus of claim 1, wherein the first SMFCI is located on an opposite side of the manifold block from the second SMFCI.

4. The apparatus of claim 3, wherein the second SMFCI and the third SMFCI are on the same side of the manifold block.

5. The apparatus of claim 3, wherein:
the first passage extends along a first passage axis that is perpendicular to a second passage axis along which the second passage extends, and
the first passage axis is perpendicular to the first SMFCI.

6. The apparatus of claim 5, wherein the first passage is a straight passage.

7. The apparatus of claim 1, wherein the corresponding second and third center axes are parallel to, and coincident with, the first reference plane.

8. The apparatus of claim 7, wherein the fifth center axis is parallel to, and coincident with, the second reference plane.

9. The apparatus of claim 8, wherein the first reference plane is parallel to the second reference plane.

10. The apparatus of claim 9, wherein the manifold block further includes a cross-passage that is internal to the manifold block and that fluidically connects the third SMFCI with the fifth SMFCI.

11. The apparatus of claim 10, wherein the manifold block is connected with a cross-passage that is external to the manifold block and that fluidically connects the third SMFCI with the fifth SMFCI.

12. The apparatus of claim 10, further comprising an outlet flow path segment, the outlet flow path segment having a first end fluidically connected with the cross-passage and a second end configured to connect with one or more components of a gas distribution system of a semiconductor processing tool.

13. The apparatus of claim 1, further comprising a first inlet flow path segment and a second inlet flow path segment, wherein:
the first inlet flow path segment is fluidically connected with the first SMFCI,
the second inlet flow path segment is fluidically connected with the fourth SMFCI, and
the first inlet flow path segment and the second inlet flow path segment are fluidically isolated from each other.

14. The apparatus of claim 13, wherein:
the first inlet flow path segment extends through a first side of the manifold block spanning between the side of the manifold block having the first SMFCI and a side of the manifold block opposite the side of the manifold block having the first SMFCI, and
the second inlet flow path segment extends through a second side of the manifold block spanning between the side of the manifold block having the first SMFCI and a side of the manifold block opposite the side of the manifold block having the first SMFCI.

15. The apparatus of claim 13, wherein:
the first inlet flow path segment and the second inlet flow path segment both extend through a first side of the manifold block spanning between the side of the manifold block having the first SMFCI and a second side of the manifold block opposite the side of the manifold block having the first SMFCI.

16. The apparatus of claim 15, wherein:
the manifold block has a width in a first direction perpendicular to the first reference plane that is 225% or less of widths of the SMFCIs in the first direction, and
the manifold block has a length in a second direction parallel to the first reference plane that is 300% or less of lengths of the SMFCIs in the second direction.

17. The apparatus of claim 16, wherein:
the set of at least five SMFCIs includes a sixth SMFCI,
the manifold block further includes a fourth passage extending between the fifth SMFCI and the sixth SMFCI, and
the sixth SMFCI is fluidically isolated from the first through fifth SMFCIs within the manifold block.

18. The apparatus of claim 17, further comprising:
the first surface-mount flow component;
the second surface-mount flow component;
the third surface-mount flow component;
the fourth surface-mount flow component;
the fifth surface-mount flow component; and
a sixth surface-mount flow component, wherein:
the first surface-mount flow component is connected with the first SMFCI;
the second surface-mount flow component is connected with the second SMFCI;
the third surface-mount flow component is connected with the third SMFCI;
the fourth surface-mount flow component is connected with the fourth SMFCI;
the fifth surface-mount flow component is connected with the fifth SMFCI; and
the sixth surface-mount flow component is connected with the sixth SMFCI.

19. The apparatus of claim 18, wherein the first and fourth surface-mount flow components are filters and the second, third, fifth, and sixth surface-mount flow components are valves.

20. The apparatus of claim 1, wherein:
the first SMFCI includes four first holes arranged in a circular pattern about the first center axis, a first center port located along the first center axis, and at least a first off-center port located radially outward of the first center port with respect to the first center axis, wherein the first center port and the first off-center port each include a corresponding first bore and a corresponding first counterbore having a larger diameter than, and centered on, the corresponding first bore,
the second SMFCI includes four second holes arranged in a circular pattern about the second center axis, a second center port located along the second center axis, and at least a second off-center port located radially outward of the second center port with respect to the second center axis, wherein the second center port and the second off-center port each include a corresponding second bore and a corresponding second counterbore having a larger diameter than, and centered on, the corresponding second bore,
the third SMFCI includes four third holes arranged in a circular pattern about the third center axis, a third center port located along the third center axis, and at least a third off-center port located radially outward of the third center port with respect to the third center axis, wherein the third center port and the third off-center port each include a corresponding third bore and a corresponding third counterbore having a larger diameter than, and centered on, the corresponding third bore,
the fourth SMFCI includes four fourth holes arranged in a circular pattern about the fourth center axis, a fourth center port located along the fourth center axis, and at least a fourth off-center port located radially outward of the fourth center port with respect to the fourth center axis, wherein the fourth center port and the fourth off-center port each include a corresponding fourth bore and a corresponding fourth counterbore having a larger diameter than, and centered on, the corresponding fourth bore, and
the fifth SMFCI includes four fifth holes arranged in a circular pattern about the fifth center axis, a fifth center port located along the fifth center axis, and at least a fifth off-center port located radially outward of the fifth center port with respect to the fifth center axis, wherein the fifth center port and the fifth off-center port each include a corresponding fifth bore and a corresponding fifth counterbore having a larger diameter than, and centered on, the corresponding fifth bore.
